(19) United States
(12) Patent Application Publication
(10) Pub. No.: US 2007/0119498 A1
(43) Pub. Date: May 31, 2007

(54) Electrode for solar cells, manufacturing method thereof and solar cell comprising the same

(76) Inventors: Young Jun Park, Suwon-si (KR); Jung Gyu Nam, Yongin-si (KR); Sang Cheol Park, Seoul (KR); Won Cheol Jung, Seoul (KR); Byung Hee Sohn, Yongin-si (KR); Eun Sung Lee, Seoul (KR)

Correspondence Address: CANTOR COLBURN, LLP, 55 GRIFFIN ROAD SOUTH, BLOOMFIELD, CT, 06002, US

(21) Appl. No.: 11/485,906

(22) Filed: Jul. 13, 2006

(30) Foreign Application Priority Data
Nov. 30, 2005 (KR) 2005-115471

(51) Int. Cl. H01L 31/00

(52) U.S. Cl. 136/256

(57) ABSTRACT

Disclosed herein is an electrode that includes a catalytic layer formed on a substrate coated with a conductive material, wherein the catalytic layer includes vertically aligned carbon nanotubes. A method of manufacturing the electrode and a solar cell comprising the electrode are also described. The electrode has increased surface roughness and a shortened charge transport pathway and, therefore, reduced charge transport resistance. Thus, when the electrode is used in a solar cell, it can improve the efficiency of the solar cell.

### CROSS-REFERENCE TO RELATED PATENT APPLICATIONS

This application claims priority to Korean Patent Application No. 10-2005-0115471, filed on Nov. 30, 2005 in the Korean Intellectual Property Office and all the benefits accruing therefrom under 35 U.S.C. §119, the contents of which are incorporated herein by reference in its entirety.

### BACKGROUND OF THE INVENTION

1. Field of the Invention

The present invention relates to an electrode for solar cells, a manufacturing method thereof, and a solar cell comprising the same. More particularly, the present invention relates to an electrode for solar cells that includes a catalytic layer formed on an electrode coated with a conductive material, wherein the catalytic layer includes vertically aligned carbon nanotubes, as well as a manufacturing method thereof and a solar cell comprising the same.

2. Description of the Related Art

Solar cells, which are photoelectric conversion devices for converting solar light to electrical energy, are more sustainable and eco-friendly than other energy sources, and have become increasingly more important over time.

In the prior art, monocrystalline or polycrystalline solar cells have frequently been used. However, these can be manufactured at high cost and limited with respect to the photoelectric conversion efficiency thereof. For these reasons, alternative technologies have been sought.

One alternative to silicon-based solar cells are organic material-based solar cells that can be manufactured at low cost. In particular, dye-sensitized solar cells having low manufacturing costs are the focus of much attention.

The dye-sensitized solar cell is a new type of photoelectrochemical solar cell manufactured in order to improve energy conversion efficiency, in which a dye, capable of producing electrons and holes by receiving visible light, is chemically adsorbed on the surface of a semiconductor material having a wide energy band gap. It has advantages in that it can be manufactured at lower costs than existing silicon solar cells or compound semiconductor solar cells, has an efficiency higher than that of organic solar cells, is eco-friendly, and can be made to be transparent.

FIG. 1 is a schematic cross-sectional view of a general dye-sensitized solar cell. The dye-sensitized solar cell includes a semiconductor electrode 10, an electrolyte layer 20, and a counter electrode 30. The semiconductor electrode 10 includes a transparent electrode 11 and a light-absorbing layer 16, which are formed on a substrate 15. The light-absorbing layer 16 has a dye 14 adsorbed on the surface of a metal oxide layer 13.

When the dye-sensitized solar cell absorbs light, the dye 14 becomes excited and oxidized. As a result, electrons are provided to the conduction band of the wide energy band gap oxide semiconductor 13, and flow through an external circuit. The oxidized dye 14 is reduced by electrons from an electron donor in the electrolyte 20. An I⁻/I₃⁻ redox mediator in the electrolyte 20 provides these electrons for reducing the oxidized dye 14. The counter electrode 30 serves as an electrocatalyst for regenerating the redox mediator.

From the photoelectric conversion mechanism described above, it is clear that the photoelectric conversion efficiency of the dye-sensitized solar cell depends on the performance of the electrode. To prevent power loss at or near the peak power of the dye-sensitized solar cell, and to increase the efficiency thereof, the above-described electrocatalytic performance of the counter electrode is important. Currently, platinum metal is widely used as the counter electrode owing to its excellent catalytic properties.

A counter electrode made of platinum is generally prepared by electron-beam evaporation or sputtering. However, the counter electrode prepared by electron-beam evaporation has shortcomings in that the film is dense and has low adhesion. On the other hand, the use of sputtering can provide excellent adhesion, suitable porosity and suitable active surface area, but can be plagued by a high manufacturing cost. In addition, metals such as platinum or gold can be corroded by an electrolyte, causing the performance of the counter electrode and the photoelectric efficiency of the solar cell to decrease over time.

It is desirable for the counter electrode to have a microstructure and therefore an increased surface area. When carbon nanotubes, as shown in FIG. 2, are applied on the counter electrode (e.g., through a wet process) in order to increase the surface area of the counter electrode, the roughness factor (surface roughness) of the counter electrode can be limited. The roughness factor of the counter electrode is an index indicating the surface area of the counter electrode that can react with an electrode, and is defined as the ratio of the actual surface area to the geometric or projected surface area of the electrode. When the roughness factor of the carbon nanotube electrode decreases, the carrier transport resistance thereof will increase, causing a problem of reduced efficiency of the solar cell.

### BRIEF SUMMARY OF THE INVENTION

The present invention overcomes the above described problems occurring in the prior art, and an aspect of the present invention includes providing an electrode for solar cells, which shows a great improvement in the efficiency of the solar cells and includes vertically aligned carbon nanotubes.

Another aspect of the present invention includes providing a method for manufacturing said electrode for solar cells.

Still another aspect of the present invention includes providing a high-efficiency solar cell having the inventive electrode.

In accordance with an exemplary embodiment of the present invention, an electrode for solar cells includes a catalytic layer formed on a substrate coated with a conductive material, in which the catalytic layer includes vertically aligned carbon nanotubes.

The inventive electrode for solar cells may also include a second catalytic layer formed on the carbon nanotube layer. This second catalytic layer may be formed of a metal selected from the group consisting of platinum, gold, silver, titanium and palladium.

In accordance with another exemplary embodiment of the present invention, a solar cell includes the first electrode, an electrolyte layer, and a second electrode.

In accordance with still another exemplary embodiment of the present invention, a method for manufacturing an electrode for solar cells includes: coating a conductive material on a transparent substrate to form a conductive film; and growing carbon nanotubes vertically on the conductive film to form a catalytic layer having the vertically aligned carbon nanotubes.

Forming the catalytic layer may include depositing metal nucleation sites for forming carbon nanotubes on the substrate having the conductive film formed thereon; and growing carbon nanotubes vertically from the metal nucleation sites. The metal of the metal nucleation sites for forming carbon nanotubes can be selected from the group consisting of nickel, iron, cobalt, palladium, platinum, and alloys thereof. The depositing can be performed using magnetron sputtering, electron-beam evaporation or a liquid catalyst-forming method. Further, the growing can be performed using vapor phase deposition such as thermal chemical vapor deposition or plasma vapor deposition.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a general dye-sensitized solar cell;

FIG. 2 is a schematic perspective view of an electrode for solar cells, manufactured by coating carbon nanotubes using a prior wet application process;

FIG. 3 is a schematic cross-sectional view of an exemplary embodiment of a counter electrode for solar cells according to the present invention;

FIG. 4 is a schematic cross-sectional view of an exemplary embodiment of a dye-sensitized solar cell according to the present invention;

FIG. 5 is a scanning electron microscope (SEM) image of a counter electrode, manufactured in Comparative Example 1;

FIG. 6a is a SEM image of the side cross-section of an exemplary embodiment of an electrode formed by growing carbon nanotubes vertically on an electrode substrate according to the present invention;

FIG. 6b is a SEM image of an exemplary embodiment of an electrode subjected to surface treatment after the vertical alignment of carbon nanotubes according to the present invention; and

FIG. 6c is a SEM image of an exemplary embodiment of an electrode having a second catalytic layer (platinum) formed on a catalytic layer consisting of vertically aligned carbon nanotubes according to the present invention.

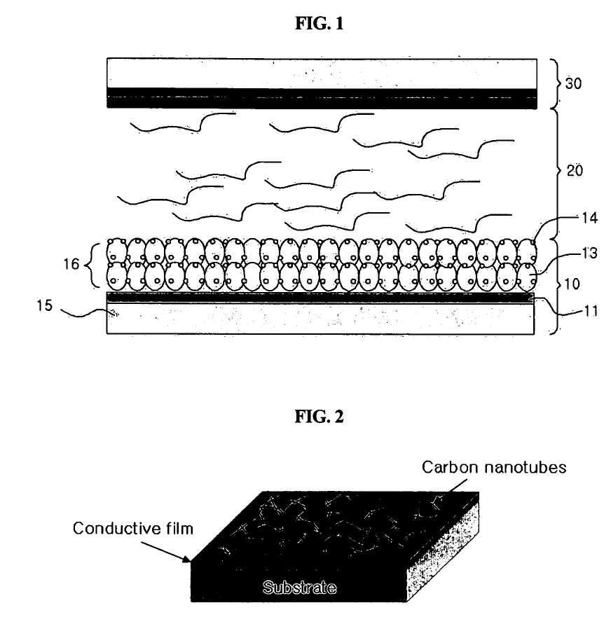

### DETAILED DESCRIPTION OF THE INVENTION

The present invention will now be described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In exemplary embodiments, the electrode for a solar cell comprises a catalytic layer formed on an electrode substrate coated with a conductive material, wherein the catalytic layer includes vertically aligned carbon nanotubes. In one embodiment, described in more detail hereinbelow, the catalytic layer consists of vertically aligned carbon nanotubes. The catalytic layer serves to promote the reduction of an electrolyte in the operation of the solar cell. In exemplary embodiments, to enhance redox catalytic effects, the surface of the counter electrode facing the transparent layer has a microstructure and therefore an increased surface area compared to surfaces without a microstructure. According to the present invention, since the electrode comprises vertically aligned carbon nanotubes, the surface roughness of the electrode increases, and thus the surface area thereof that can react with an electrolyte layer increases. Also, since charges are generally transported directly to the electrode along the shortest path without passing through other parts, the charge transport pathway is shortened, so that the charge transport resistance of the electrode is reduced. Accordingly, the efficiency of a solar cell comprising the electrode is improved.

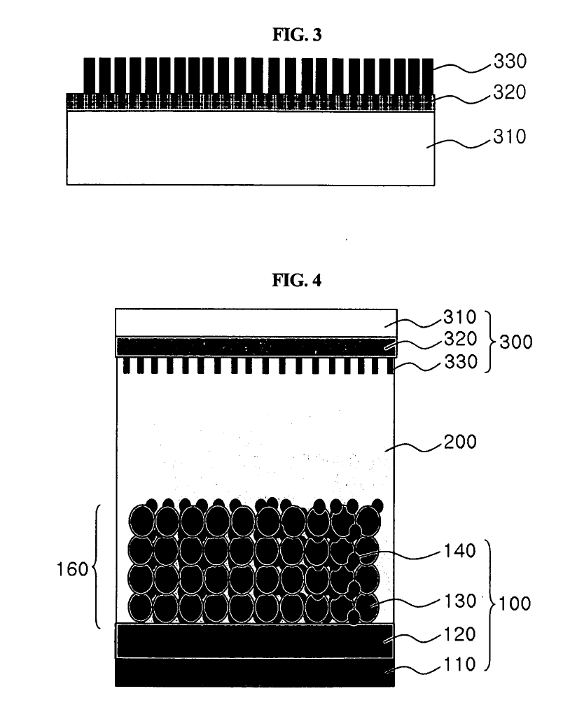

FIG. 3 is a cross-sectional schematic view illustrating the structure of an electrode for solar cells according to an exemplary embodiment of the present invention. The electrode for solar cells comprises a conductive film 320 formed of a conductive material coated on an electrode substrate 310, and a catalytic layer 330 formed on the conductive film 320, wherein the catalytic layer 330 includes the vertically aligned carbon nanotubes. In an exemplary embodiment, as shown in FIG. 3, the catalytic layer 330 consists of the vertically aligned carbon nanotubes. The thickness of the catalytic layer of the vertically aligned carbon nanotubes 330 is not specifically limited. In an exemplary embodiment, the thickness of the catalytic layer 330 is about 1 to about 50 nanometers (nm), because if the carbon nanotubes are too long, they can be difficult to maintain in a vertically aligned state. As used herein, “vertically aligned” implies that, at the very least, the major longitudinal axes of at least 90 percent of the carbon nanotubes are substantially parallel to each other. By “substantially parallel”, it is meant that the angle formed from a free end of one carbon nanotube to the free end of another adjacent carbon nanotube, with the point of attachment of the carbon nanotubes to the substrate being the vertex of the angle, is less than about 15 degrees.

In order to increase the catalytic activity of the electrode, the electrode may further comprise an optional second catalytic layer disposed on the catalytic layer of vertically aligned carbon nanotubes 330. The second catalytic layer may be formed of a material having a low work function including, but not necessarily limited to, platinum, gold, silver, titanium and palladium.

The substrate 310 for the electrode may be a metal plate, a transparent inorganic substrate made of, for example, quartz or glass, or a transparent polymeric substrate made of, for example, polyethylene terephthalate (PET), polyethylene naphthalate (PEN), polycarbonate, polystyrene, polypropylene, or the like.

The conductive film 320, which is disposed onto the substrate 310, may comprise indium tin oxide (ITO), fluorine-doped tin oxide (FTO), ZnO—Ga₂O₃, ZnO—Al₂O₃, and SnO₂—Sb₂O₃, but are not limited thereto. In addition, other examples of the conductive material that can be used include polyacetylenes, such as polydiphenylacetylene, poly(t-butyl)diphenylacetylene, poly(trifluoromethyl)diphenylacetylene, poly(bistrifluoromethyl)acetylene, polybis(t-butyldiphenyl)acetylene, poly(trimethylsilyl)diphenylacetylene, poly(carbazol)diphenylacetylene, polydiacetylene, polyphenylacetylene, polypyridinacetylene, polymethoxyphenylacetylene, polymethylphenylacetylene, poly(t-butyl)phenylacetylene, polynitro-phenylacetylene, poly(trifluoromethyl)phenylacetylene, poly(trimethylsilyl)phenylacetylene, and derivatives thereof, as well as polythiophenes.

The conductive material can be coated onto the substrate using general coating processes, for example, spraying, spin coating, dipping, printing, doctor blading, sputtering, or the like.

In another aspect, the present invention is directed to a method for manufacturing the electrode for a solar cell.

To manufacture the electrode the conductive material is coated on the electrode substrate 310 to form the conductive film 320. Then, carbon nanotubes are grown vertically on the conductive film 320 to form the catalytic layer of vertically aligned carbon nanotubes 330.

To form the catalytic layer 330 on the conductive film 320, metal nucleation sites or metal catalysts for forming carbon nanotubes are first deposited on the substrate 310 having the conductive film 320 formed thereon. Specifically, on the surface of the electrode substrate 310 having the conductive film 320 formed thereon, the metal is deposited to a given thickness through magnetron sputtering, e-beam evaporation or a liquid catalyst-forming processes, so as to form the metal nucleation sites for growing the carbon nanotubes.

In an exemplary embodiment, the metal nucleation sites for forming the carbon nanotubes comprise a metal selected from the group consisting of nickel, iron, cobalt, palladium, platinum and alloys thereof. In an exemplary embodiment, the metal nucleation sites for forming the carbon nanotubes are deposited to a thickness of about 0.1 to about 10 nm.

Then, using chemical vapor deposition (CVD) or plasma enhanced chemical vapor deposition (PECVD), carbon nanotubes are grown vertically from the metal nucleation sites.

During the growth of the carbon nanotubes, a carbon-containing gas, such as methane, acetylene, ethylene, ethane, carbon monoxide, carbon dioxide, or the like is injected, along with H₂, N₂ or Ar gas, into a reaction furnace maintained at a temperature of about 400 to about 600 degrees Celsius (° C.). Under such conditions, the carbon nanotubes are believed to grow from the decomposition of carbonaceous gas on the surface of the metal nucleation sites. The carbon of carbonaceous gas is dissolved in the metal nucleation site layer and diffuses out through the metal nucleation site layer, so that the carbon nanotubes grow vertically. The vertically grown carbon nanotubes form an electric field with the substrate 310 and align themselves and grow under the influence of the metal nucleation sites having magnetism. The carbon nanotubes can support each other because they are grown densely, and thus align themselves to grow vertically. The carbon nanotube growth time can be about 1 to about 30 minutes. Using the growth temperature and time, the length of the carbon nanotubes can be controlled as desired.

Since the surfaces of a carbon nanotube is hydrophobic, it can be made hydrophilic so as to more easily interact with an electrolyte. Therefore, after the vertically aligned carbon nanotubes are grown, they can be surface treated with a plasma such as an O₂ plasma, or an acid such as hydrochloric acid, sulfuric acid, and nitric acid. In addition, during this surface treatment process, some of the carbon nanotubes can decompose or break apart. Consequently, if desired, the density of the vertically aligned carbon nanotubes can be controlled using the surface treatment process.

The density of the vertically aligned carbon nanotubes can also be controlled using other methods. For example, the density of the carbon nanotubes can be controlled by controlling the density of the metal nucleation sites on the conductive film.

If there is a desire to enhance the catalytic activity of the inventive electrode for a particular application or use of the solar cell, the optional second catalytic layer can be formed on the catalytic layer of vertically aligned carbon nanotubes 330. As described above, the second catalytic layer may be formed of platinum, gold, silver, titanium, or palladium, but is not necessarily limited thereto. The second catalytic layer may be formed using electron-beam evaporation, sputtering, or electrochemical deposition.

The electrode disclosed herein can be used as a counter electrode for various types of solar cells. In addition to solar cells, the electrode can also be used in photoelectrochromic devices, solar cell-driven display devices, and the like. Since the electrode can increase photoelectric conversion efficiency when applied to photoelectric conversion devices, a high-efficiency photoelectric device can be made.

Thus, in an exemplary embodiment, a solar cell includes a first electrode having vertically aligned carbon nanotubes as described above, an electrolyte layer, and a second electrode. Specifically, the solar cell may comprise a first electrode comprising a catalytic layer comprising vertically aligned carbon nanotubes; a second electrode disposed opposing the first electrode, the second electrode comprising a transparent electrode made of a conductive material coated on a substrate, a metal oxide layer disposed on the transparent electrode, and a dye adsorbed on the surface of the metal oxide layer; and an electrolyte layer interposed between the first electrode and the second electrode.

As described above, the first electrode of the solar cell may further comprise an optional second catalytic layer disposed on the carbon nanotube catalytic layer and made from a low-work-function metal.

FIG. 4 illustrates a cross-sectional schematic view of an exemplary embodiment of a dye-sensitized solar cell according to the present invention. The solar cell comprises a first electrode 300, an electrolyte 200, and a second electrode 100. The second electrode 100 includes a transparent conducting electrode 120 formed on a substrate 110, and a light-absorbing layer 160 having a dye 140 adsorbed on the surface of a metal oxide 130. The first electrode 300 includes a conductive film 320 coated on a substrate 310 and a catalytic layer of vertically aligned carbon nanotubes 330. The solar cell has increased photoelectric conversion efficiency because the surface area of the first electrode is enlarged, and thus its catalytic activity is increased.

The metal oxide 130 of the second electrode 100 can be formed on a surface of the transparent conducting electrode 120. The metal oxide layer 130 can be made of any oxide without particular limitation, including an oxide of titanium, niobium, hafnium, tungsten, indium, tin, zinc, or a combination comprising at least one of the foregoing metals. Exemplary metal oxides include TiO₂, SnO₂, ZnO, WO₃, Nb₂O₅, and TiSrO₃. In an exemplary embodiment, the anatase polytype of TiO₂ is used.

In exemplary embodiments, the metal oxide layer 130 has an increased surface area in order to enable the dye 140 adsorbed on the surface thereof to absorb more light and to enhance the adhesion thereof to the electrolyte layer 200. For example, the metal oxide layer 130 can have a nanostructure, and can comprise nanotubes, nanowires, nanobelts, nanoparticles, or like nanostructured materials. As used herein, the term “nanostructured” refers to those materials having an average longest grain dimension of about 500 nm. Specifically, an average longest grain dimension of the metal oxide can be about 1 to about 200 nm, and more specifically about 5 to about 100 nm. It is also possible to use a mixture of at least two metal oxides having different grain dimensions in order to scatter incident light and increase quantum yield.

Any material may be used as the dye 140, without limitation, as long as it has a charge separation function and is photosensitive. Exemplary dyes 140 include ruthenium complexes such as RuL₂(SCN)₂, RuL₂(H₂O)₂, RuL₃, and RuL₂, wherein L represents 2,2′-bipyridinyl-4,4′-dicarboxylate or the like. In addition to ruthenium complexes, other examples of dyes 140 that can be used include xanthine dyes such as rhodamine B, Rose Bengal, eosin, or erythrosine; cyanine dyes such as quanocyanine or cryptocyanine; basic dyes such as phenosafranine, capri blue, thiosine or methylene blue; porphyrin type compounds such as chlorophyll, zinc porphyrin, or magnesium porphyrin; azo dyes; phthalocyanine compounds; complex compounds such as ruthenium trispyridyl, anthraquinone-based dyes; polycyclic quinone-base dyes; or the like, or a combination comprising at least one of the foregoing dyes.

Any electrolyte 200 can be used, without limitation, as long as it has a function of conducting holes. Exemplary electrolytes 200 include tetrabutylammonuim iodide, lithium iodide, methylethylimidazolium iodide, methylpropylimidazolium iodide and a solution of iodine in non-protonic polar solvents, for example, acetonitrile, ethyl carbonate, methoxypropionitrile, and propylene carbonate. It is also possible to use solid electrolytes 200, such as triphenylmethane, carbazole, and N,N′-diphenyl′-N,N′-bis(3-methylphenyl)-1,1′-biphenyl)-4,4′-diamine (TPD).

The solar cell operates in the following manner. The dye 140 adsorbed on the surface of the metal oxide layer 130 absorbs light which was incident into the light-absorbing layer 160 through the transparent electrode 120. Electrons move from the ground state to the excited state of the dye 140 to make electron-hole pairs, and the electrons in the excited state are injected into the conduction band of the metal oxide 130 and then move to the electrode, thus generating electromotive force. When the electrons generated in the dye 140 by light excitation move to the conduction band of the metal oxide 130, the dye 140 that lost electrons will be returned to its original ground state by receiving electrons from the hole transfer material of the electrolyte 200.

The method for manufacturing the dye-sensitized solar cell having this structure is not specifically limited, and any method known in the art can be used without any particular limitation. For example, to manufacture a solar cell using the semiconductor electrode, the semiconductor electrode and a counter electrode are disposed opposite each other. A space to be filled with an electrolyte is formed and the electrolyte can be injected into the space.

Hereinafter, the present invention will be described in detail with reference to examples. It is to be understood, however, that these examples are for illustrative purposes only and are not to be construed to limit the scope of the present invention.

### EXAMPLE 1

Indium tin oxide (ITO) was applied on an organic substrate by sputtering, and then metal nucleation sites made of Invar (a 42 wt % Ni, 52 wt % Fe, and 6 wt % Co alloy) were deposited thereon to a thickness of 2 nm using e-beam evaporation. Then, carbon nanotubes were induced to grow vertically from the metal nucleation sites through thermal chemical vapor deposition by feeding acetylene and argon into a reaction furnace maintained at a temperature of 500° C., while allowing the gas to react with the metal nucleation sites for 10 minutes.

After completion of the growth of the carbon nanotubes, the surface of the grown carbon nanotubes was treated with plasma using a reactive ion etcher (RIE). The surface treatment was carried out with O₂ plasma at a power of 300 watts (W) and a pressure of 30 millitorr (mtorr) for 30 seconds.

Meanwhile, on a glass substrate coated with ITO, a paste of TiO₂ particles having an average particle size of about 12 micrometers (μm) was applied using screen printing, and dried at 450° C. for 30 minutes. After completion of the drying step, the substrate was placed in an electric furnace, in which it was heated at a rate of 3 degrees Celsius per minute (° C./min) in an inert atmosphere, and maintained at 450° C. for 30 minutes and then cooled at a rate of 3° C./min, thus forming a porous TiO₂ film having a thickness of about 15 μm.

Then, the glass substrate having the metal oxide layer formed thereon was immersed in an 0.3 millimolar (mM) solution of cis-bis(isothiocyanato)bis(2,2′-bipyridyl-4,4′-dicarboxylato)-ruthenium for 20 hours, followed by drying, so that said dye was adsorbed on the surface of the TiO₂ layer. After completion of adsorption of the dye, in order to wash out unadsorbed dye existing on the light-absorbing layer, the substrate was washed with ethanol, followed by drying.

The above-obtained electrode including the vertically aligned carbon nanotubes (first electrode), and the electrode having the light-absorbing layer formed thereon (second electrode), were assembled together such that the conductive surface of the second electrode was placed within the cell facing the carbon nanotubes of the first electrode. At this time, a SURLYN film (100 μm thick; commercially available from DuPont) was inserted between the two electrodes, and the electrodes were pressed against each other on a heating plate to a thickness of about 120 μm under 2 atmospheres (atm) of pressure.

Then, an electrolyte solution was charged into the space between the two electrodes, thus obtaining a dye-sensitized solar cell. The electrolyte solution used herein was an I₃⁻/I⁻ electrolyte solution obtained by dissolving 0.6 M 1,2-dimethyl-3-octyl-imidazolium iodide, 0.2M LiI, 0.04M I₂ and 0.2M 4-tert-butyl-pyridine (TBP) in acetonitrile.

### EXAMPLE 2

A solar cell was manufactured in the same manner as in Example 1, except that platinum was deposited on the O₂ plasma-treated carbon nanotubes using electron-beam evaporation (room temperature, 1×10⁻⁶ torr pressure, and 20 nm thickness).

### COMPARATIVE EXAMPLE 1

A solar cell was manufactured in the same manner as in Example 1, except that platinum was deposited on the ITO-coated substrate to a thickness of 20 nm to serve as the counter electrode.

### COMPARATIVE EXAMPLE 2

A solar cell was manufactured in the same manner as in Example 1, except that a counter electrode was formed by treating carbon nanotubes with hydrochloric acid, dispersing the treated carbon nanotubes in methanol at a concentration of 0.05 wt % to prepare a coating solution, and spin-coating the coating solution on the ITO-coated substrate, followed by drying (70° C. for 30 min).

### TEST EXAMPLE 1

### Observation of Carbon Nanotube Layer

The structures of the counter electrodes prepared in Examples 1 and 2 and Comparative Example 2 were observed using scanning electron microscopy.

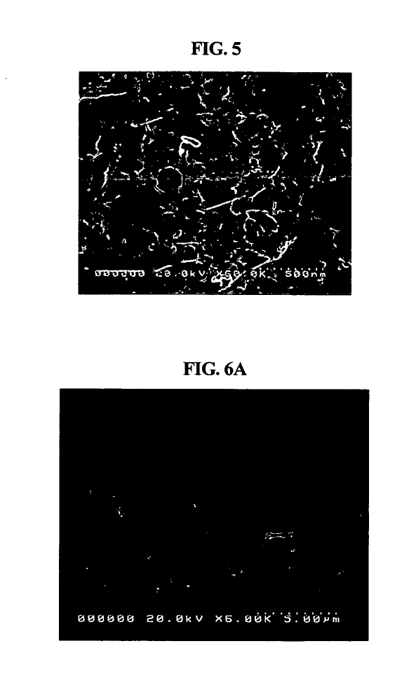

FIG. 5 is a scanning electron microscope (SEM) image of the surface of the electrode obtained according to Comparative Example 2. As shown in FIG. 5, the carbon nanotubes are not vertically aligned, but instead transversely aligned, increasing the roughness factor (surface roughness).

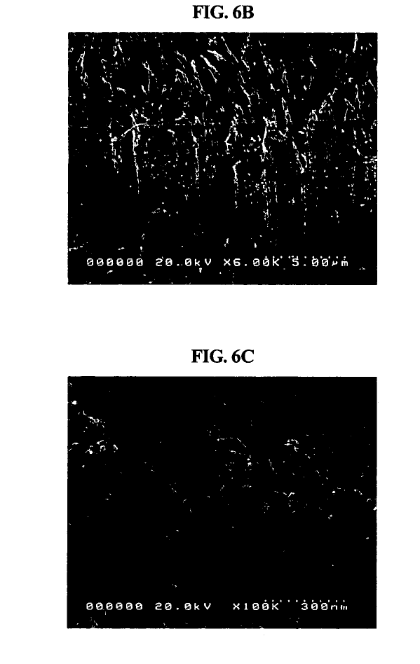

FIG. 6a is a SEM image of the side cross-section of the electrode where the carbon nanotubes formed on the electrode substrate having the conductive film formed thereon have been vertically aligned. FIG. 6b is a scanning electron microscope photograph showing the electrode after the grown carbon nanotubes have been treated with O₂ plasma using RIE for 30 seconds. FIG. 6c is a SEM image showing the electrode where platinum as the second catalytic layer (Pt) has been deposited on the O₂ plasma-treated carbon nanotubes to a thickness of 20 nm using electron-beam evaporation. As can be seen in FIG. 6a, the electrode for solar cells has an increased surface area for interacting with an electrolyte, because the carbon nanotubes are vertically aligned.

### TEST EXAMPLE 2

### Evaluation of Photoelectric Conversion Efficiency

The photovoltage and photocurrent of each of the photoelectric conversion devices manufactured in Examples 1 and 2 as well as in Comparative Examples 1 and 2 were measured to calculate photoelectric conversion efficiency. As a light source, a xenon lamp (Oriel, 01193) was used, and the sunlight property (AM 1.5) of the Xenon lamp was calibrated using a reference solar cell (Furnhofer Institute Solare Engeriessysteme, Certificate No. C-ISE369, Type of material: Mono-Si⁺ KG filter). Photocurrent density (I_{sc}), open voltage (V_{oc}) and filler factor (FF), which have been calculated from the above measured photocurrent-voltage curve, were substituted into Equation 1 to calculate photoelectric efficiency (ηₑ). The results are shown in Table 1 below.
ηₑ(%)=(V_{oc}×I_{sc}×FF)/(P_{inc})×100 [Equation 1]

wherein P_{inc} denotes 100 mW/cm² (1 sun).

TABLE 1

| | I_{sc} (mA) | V_{oc} (mV) | FF | Photoelectric efficiency |
|---|---|---|---|---|
| Comparative | 9.728 | 649.049 | 0.507 | 3.055 |
| Example 1 | | | | |
| Comparative | 6.573 | 602.356 | 0.298 | 1.178 |
| Example 2 | | | | |
| Example 1 | 8.352 | 643.755 | 0.547 | 2.941 |
| Example 2 | 9.002 | 656.499 | 0.554 | 3.272 |

As shown in Table 1, the solar cell comprising the electrodes (counter electrode) having vertically aligned carbon nanotubes have increased photoelectric conversion efficiency, because the counter electrode has an increased surface roughness (surface area) and therefore, an increased electron transport resistance. Particularly when the second catalytic layer (platinum) is formed on the catalytic layer of vertically aligned carbon nanotubes, the efficiency of the solar cell was further increased.

As described herein, the solar cell electrode according to the present invention, has an increased surface roughness and a shortened charge transport pathway, because the carbon nanotubes are vertically aligned. This allows the charge transport resistance in the electrode to be reduced. Accordingly, when the electrode is used as a counter electrode in solar cells, the photoelectric density (I_{oc}) and open voltage (V_{oc}) of the solar cells will both increase, thus increasing the photoelectric conversion efficiency. As a result, the use of the inventive electrode can provide a high-efficiency solar cell.

In addition, according to the present invention, an expensive platinum electrode can be substituted with the disclosed electrode, and thus a high-efficiency solar cell can be provided at low cost, and a problem of the corrosion of electrodes by an electrolyte can be solved.

Although the present invention has been described with reference to the foregoing exemplary embodiments, these exemplary embodiments do not serve to limit the scope of the present invention. Accordingly, those skilled in the art to which the present invention pertains will appreciate that various modifications, additions and substitutions are possible, without departing from the scope and spirit of the accompanying claims.

What is claimed is:

1. An electrode for solar cells, comprising a catalytic layer formed on a substrate coated with a conductive material, wherein the catalytic layer comprises vertically aligned carbon nanotubes.

2. The electrode of claim 1, wherein the catalytic layer has a thickness of about 1 to about 50 nanometers.

3. The electrode of claim 1, further comprising a second catalytic layer formed on the catalytic layer comprising the vertically aligned carbon nanotubes.

4. The electrode of claim 3, wherein the second catalytic layer comprises a metal selected from the group consisting of platinum, gold, silver, titanium, and palladium.

5. The electrode of claim 1, wherein the substrate is an inorganic substrate, a metal plate, or a polymeric substrate.

6. The electrode of claim 1, wherein the conductive material is selected from the group consisting of indium tin oxide, fluorine-doped tin oxide, ZnO—Ga₂O₃, ZnO—Al₂O₃, SnO₂—Sb₂O₃ and conductive polymers.

7. A method for manufacturing an electrode for solar cells, the method comprising:
coating a transparent substrate with a conductive material to form a conductive film; and
growing carbon nanotubes vertically on the conductive film to form a catalytic layer.

8. The method of claim 7, further comprising depositing a metal nucleation site for forming carbon nanotubes on the conductive film prior to the growing the carbon nanotubes, wherein the carbon nanotubes grow vertically from the metal nucleation sites.

9. The method of claim 8, wherein the depositing the metal nucleation sites comprises magnetron sputtering, electron-beam evaporation, or liquid catalyst-forming.

10. The method of claim 8, wherein the metal of the metal nucleation sites is selected from the group consisting of nickel, iron, cobalt, palladium, platinum, and alloys thereof.

11. The method of claim 7, wherein growing the carbon nanotubes comprises vapor deposition.

12. The method of claim 11, wherein the vapor deposition is thermal chemical vapor deposition or plasma vapor deposition.

13. The method of claim 7, wherein the growing the carbon nanotubes occurs in a reaction furnace at a temperature of about 400 to about 600 degrees Celsius for about 1 to about 30 minutes while a carbon-containing gas selected from the group consisting of methane, acetylene, ethylene, ethane, carbon monoxide and carbon dioxide is injected into the reaction furnace together with H₂, N₂, or Ar.

14. The method of claim 7, further comprising treating the vertically aligned carbon nanotubes with a plasma or an acid.

15. The method of claim 7, further comprising forming a second catalytic layer on the catalytic layer comprising the vertically aligned carbon nanotubes.

16. The method of claim 15, wherein the second catalytic layer comprises a metal selected from the group consisting of platinum, gold, silver, titanium, and palladium.

17. The method of claim 15, wherein forming the second catalytic layer comprises electron-beam sputtering, chemical vapor deposition, or electrochemical deposition.

18. A solar cell, comprising a first electrode, an electrolyte, and a second electrode, wherein the first electrode comprises a catalytic layer formed on a substrate coated with a conductive material, wherein the catalytic layer comprises vertically aligned carbon nanotubes.

19. The solar cell of claim 18, wherein the second electrode is disposed to face the first electrode, wherein the second electrode comprises a transparent conducting electrode coated on a substrate, a metal oxide layer disposed on the transparent conducting electrode, and a dye adsorbed on a surface of the metal oxide layer; and wherein the electrolyte is interposed in a space between the first electrode and the second electrode.

20. The solar cell of claim 18, wherein the catalytic layer has a thickness of about 1 to about 50 nanometers.

21. The solar cell of claim 18, wherein the first electrode further comprises a second catalytic layer.

22. The solar cell of claim 21, wherein the second catalytic layer comprises a metal selected from the group consisting of platinum, gold, silver, titanium, and palladium.
